(19) United States
(12) Patent Application Publication
(10) Pub. No.: US 2014/0370703 A1
(43) Pub. Date: Dec. 18, 2014

(54) TSV Front-top Interconnection Process

(71) Applicant: NATIONAL CENTER FOR ADVANCED PACKAGING CO., LTD., Wuxi City (CN)

(72) Inventors: Fengwei Dai, Wuxi (CN); Daquan Yu, Wuxi (CN)

(21) Appl. No.: 14/272,293

(22) Filed: May 7, 2014

(30) Foreign Application Priority Data
Jun. 13, 2013 (CN) 201310233922.2

(51) Int. Cl. H01L 21/768; H01L 21/288

(52) U.S. Cl. CPC H01L 21/76898; H01L 21/76877; H01L 21/2885; H01L 21/76883; H01L 21/76831
USPC 438/660

(57) ABSTRACT

A TSV front-top interconnection process is provided. In an embodiment of the present invention, the stress concentration area of a TSV copper pillar is eliminated, which reduces the possibility of generating delamination or cracks between an insulating layer and the substrate due to stress. Meanwhile, the defect of the existing process that the TSV copper pillar may expose after an electroplating and annealing process is re-used to achieve the interconnection between the TSV copper pillar and the metal redistribution layer.

### CROSS-REFERENCE TO RELATED APPLICATION

This application claims priority from CN Patent Application Serial No. 201310233922.2, filed on Jun. 13 2013, the entire contents of which are incorporated herein by reference for all purposes.

### FIELD OF THE INVENTION

The present invention is related to semiconductor integration technology, especially related to a TSV front-top interconnection process.

### BACKGROUND OF THE INVENTION

As the constant development of microelectronic technology, the feature size of the integrated circuit decreases, and the interconnection density increases. At the same time, customers have an increasing demand for high performance and low power consumption. In this case, due to equipment process limitation and materials properties, the way of further reducing the interconnection line width to improve the performance is limited. Hence, the resistance-capacitance (RC) delay gradually becomes the bottleneck of the performance of the semiconductor chip.

Through silicon via (TSV) process can realize the 3D interconnection between wafers (chips) or between a chip and a substrate by producing metal columns in wafers with metal bumps, which can make up for the limitations of traditional 2D wiring of semiconductor chips. Compared with the traditional stacking techniques including the bonding technique, this interconnection method has increased the 3D stacking density and reduced packaging dimension, thus it can greatly improve the speed of the chip and reduce the power consumption. Therefore, TSV technique is becoming one of the key techniques for the high density packaging, and is considered as the fourth generation package technology after Wire bonding, TAB, Flip-chip.

TSV is a technique that produces vertical via holes between chips or between wafers, and deposits the conductive material in vertical via holes by using the methods including electroplating to realize the interconnection. However, the existing TSV front-top interconnection process has following disadvantages:

For the TSV with small diameter and high depth-to-width ratio, copper pillars in the TSV are obviously expose from the silicon substrate surface after a via-filling using copper electroplating and an annealing process. The exposing part of the copper pillar is required to be removed by additional processes, which increase the cost.

In the prior isotropic dry etching process of TSV, a protrusion will appear at the edge of the TSV. When depositing a SiO₂ insulating layer, a seed layer and during a copper via-filling, a stress concentration area with multilayer structure is formed, which may generate delamination or cracks between an insulating layer and a substrate, which seriously affects the quality and reliability of TSV, and the influence of the stress concentration area cannot be eliminated through the prior processes.

To meet the coverage requirement of the insulating layer (SiO₂) in the TSV, the insulating layer on the surface is generally very thick during the deposition process, which will produce large SiO₂ membrane stress, and further affect the quality and reliability of TSV.

Moreover, during a CMP (Chemical Mechanical Polishing) process on the wafer, it is required to control the polishing accuracy in order to retain a certain thickness of the insulating layer on the silicon surface, which greatly increases the difficulty of the process.

Therefore, to solve the above technical problems, it is necessary to provide a new TSV front-top interconnection process.

### SUMMARY OF THE INVENTION

The present invention provides a TSV front-top interconnection process, which can reduce the difficulty of the process, and improve the quality and reliability of the TSV.

To achieve the purpose of the present invention, the technical scheme provided by embodiments of the present invention can be described as follows:

A TSV front-top interconnection process provided includes:

etching a TSV on a substrate;

preparing an insulating layer on the inner wall of the TSV and on the substrate surface;

electroplating the TSV and the surface of the insulating layer to form a TSV copper pillar;

implementing a chemical mechanical polishing process to remove overburden copper layer of the substrate surface, the insulating layer and certain thickness of the substrate.;

annealing the TSV copper pillar to make the TSV copper pillar expose a certain height from the substrate;

preparing a passivation layer on the surface of the substrate and the TSV copper pillar;

removing certain part of the passivation layer to make the top of the TSV copper pillar expose from the passivation layer.

In the present invention, the stress concentration area of the TSV copper pillar is eliminated; The defect that the protrusions of the TSV copper pillars appear due to annealing in the prior art is re-used as an advantage to achieve the interconnection in the present invention; and it is not necessary to precisely control the accuracy of CMP process.

### BRIEF DESCRIPTION OF THE DRAWINGS

To give a further description of the embodiments in the present invention or the prior art, the appended drawings used to describe the embodiments and the prior art will be introduced as follows. Obviously, the appended drawings described here are only used to explain some embodiments of the present invention. Those skilled in the art can understand that other appended drawings may be obtained according to these appended drawings without creative work.

FIG. 1a-1f illustrate the flow diagram of a TSV front-top interconnection process in the prior art;

FIG. 2 illustrates the flow diagram of a TSV front-top interconnection process in an embodiment of the present invention;

FIG. 3a-3h illustrate the flow diagram of a TSV front-top interconnection process in an embodiment of the present invention.

### DETAILED DESCRIPTION OF THE INVENTION

The embodiments of the present invention are described more fully hereinafter with reference to the accompanying drawings, which form a part hereof, and which show, by way of illustration, specific exemplary embodiments by which the invention may be practiced. This invention may, however, be embodied in many different forms and should not be construed as limited to the embodiments set forth herein; rather, these embodiments are provided so that this disclosure will be through and complete, and will fully convey the scope of the invention to those skilled in the art. Among other things, the present invention may be embodied as systems, methods or devices. The following detailed description should not to be taken in a limiting sense.

Throughout the specification and claims, the following terms take the meanings explicitly associated herein, unless the context clearly dictates otherwise. The phrase “in one embodiment” as used herein does not necessarily refer to the same embodiment, though it may. Furthermore, the phrase “in another embodiment” as used herein does not necessarily refer to a different embodiment, although it may. Thus, as described below, various embodiments of the invention may be readily combined, without departing from the scope or spirit of the invention.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on”. The term “coupled” implies that the elements may be directly connected together or may be coupled through one or more intervening elements. Further reference may be made to an embodiment where a component is implemented and multiple like or identical components are implemented.

While the embodiments make reference to certain events this is not intended to be a limitation of the embodiments of the present invention and such is equally applicable to any event where goods or services are offered to a consumer.

Further, the order of the steps in the present embodiment is exemplary and is not intended to be a limitation on the embodiments of the present invention. It is contemplated that the present invention includes the process being practiced in other orders and/or with intermediary steps and/or processes.

In order to better explain the creativity of embodiments of the present invention, a TSV front-top interconnection process in the prior art is described firstly. The prior TSV front-top interconnection process includes following steps :

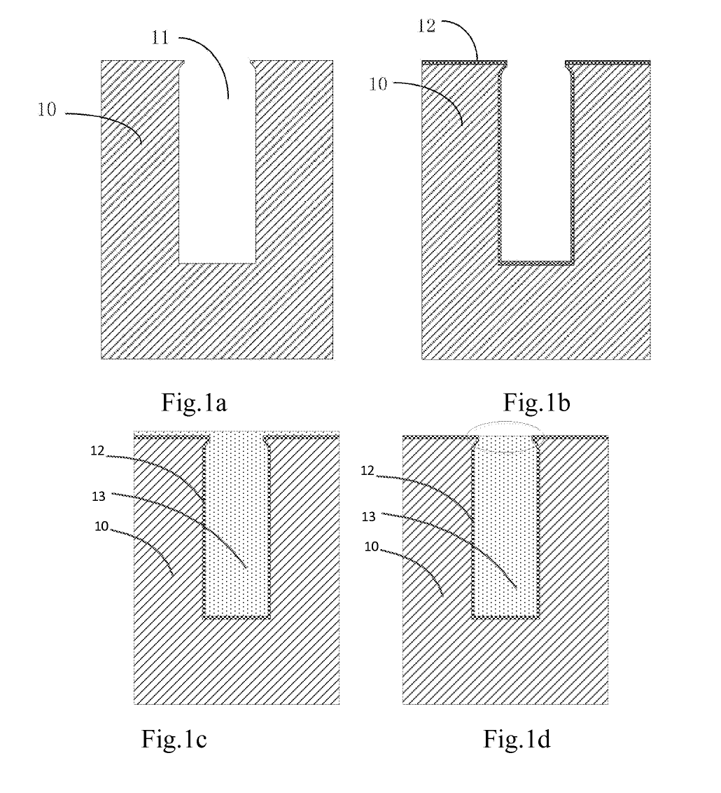

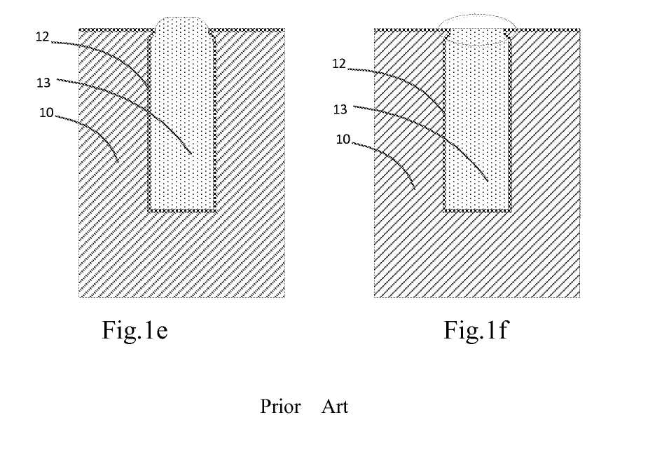

A TSV11 is etched on a substrate 10, as shown in FIG. 1a.

An insulating layer 12 is prepared on the inner wall of the TSV11 and on the substrate 10 surface, as shown in FIG. 1b.

The TSV 11 and the surface of the insulating layer 12 are electroplated to form a TSV copper pillar 13, as shown in FIG. 1c.

A CMP process is implemented to remove the overburden copper, and a certain thickness of the insulating layer 12 is retained, as shown in FIG. 1d.

The TSV copper pillar 13 is annealed, as shown in FIG. 1e. Due to the annealing process, the TSV copper pillar 13 exposes a certain height from the substrate to form a protrusion.

A second CMP process is implemented to remove the protrusion, as shown in FIG. 1f.

Thus, a metal interconnection structure of the TSV copper pillar 13 can be formed on the substrate 10.

As described above, in the two CMP processes, the polishing accuracy should be controlled strictly. Each TSV copper pillar finally obtained still has two stress concentration areas at the corner of its top. So the present invention aims to eliminate the stress concentration area of the TSV copper pillar, and reduce the difficulty of the process.

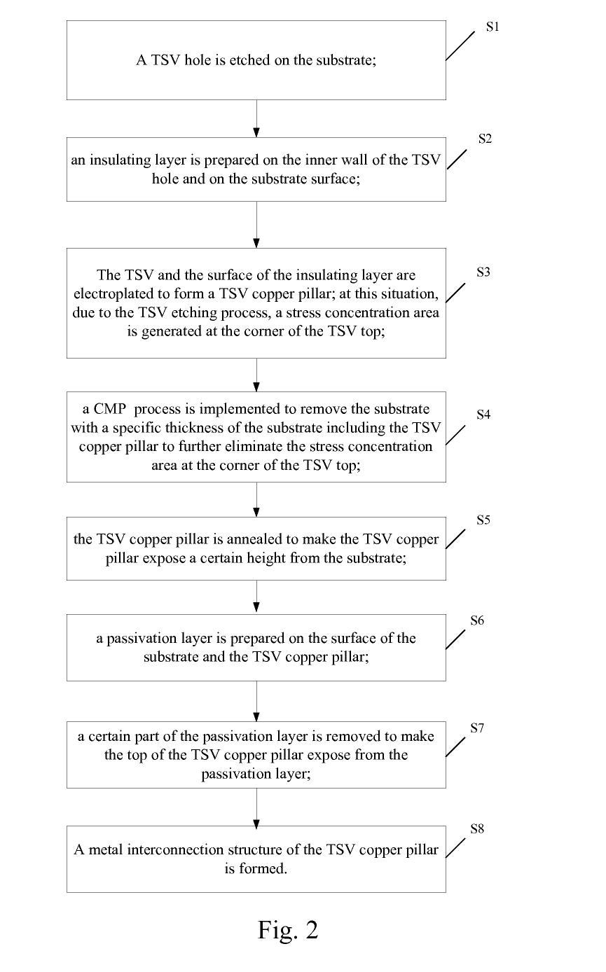

FIG. 2 illustrates the flow diagram of a TSV front-top interconnection process in an embodiment of the present invention. As shown in FIG. 2, a TSV front-top interconnection process in an embodiment of the present invention includes following steps:

S1: a TSV is etched on a substrate;

S2: An insulating layer is prepared on the inner wall of the TSV and on the substrate surface;

S3: the TSV and the surface of the insulating layer are electroplated to form a TSV copper pillar. At this situation, due to the TSV etching process, a stress concentration area is generated at the corner of the TSV top;

S4: a CMP process is implemented to remove the substrate with a specific thickness of the substrate including the overburden copper layer of the substrate surface, the insulating layer and certain thickness of the substrate to further eliminate the stress concentration area at the corner of the TSV top;

S5: The TSV copper pillar is annealed to reduce stress; after annealed, the TSV copper pillar exposes a certain height from the substrate to form a protrusion;

S6: A passivation layer is prepared on the surface of the substrate and the TSV copper pillar;

S7: A certain part of the passivation layer (which covers the TSV copper pillar) is removed to make the top of the TSV copper pillar (the top of the protrusion) exposes from the passivation layer;

S8: A metal interconnection structure of the TSV copper pillar is formed.

By using the technical scheme of the present invention, steps in the prior art are adjusted and amended. In the present invention, the insulating layer and the stress concentration area are removed firstly, since the insulating layer need not to be kept, the precise of the CMP need not to be controlled. Because in the present invention, the passivation layer is added after annealing process, the exposed TSV copper pillar need not be removed, on the contract, the exposed TSV copper pillar is reused as part of interconnection structure.

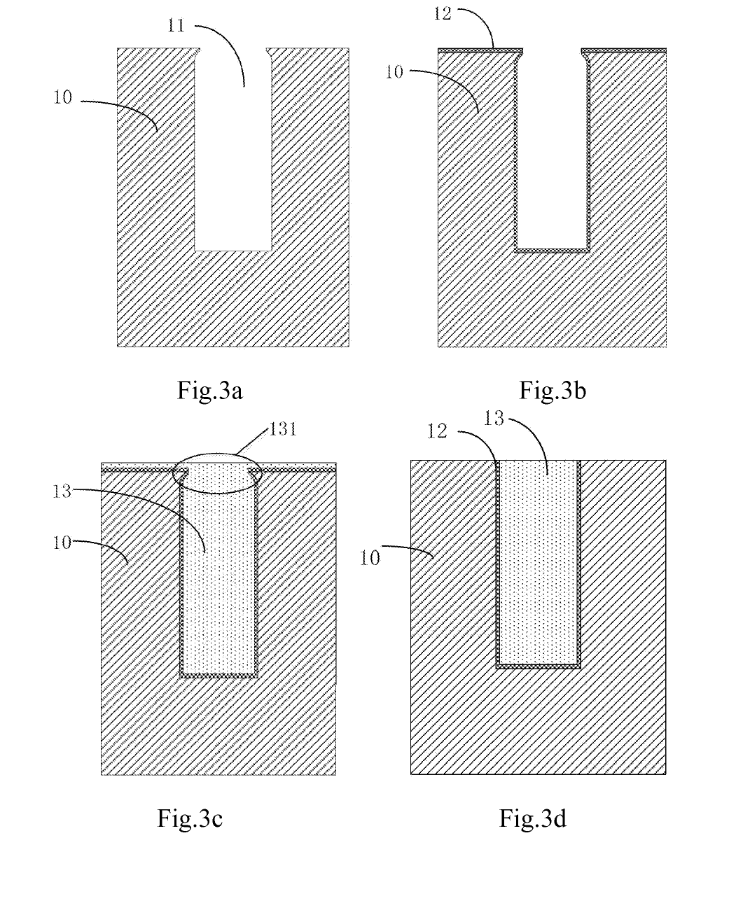

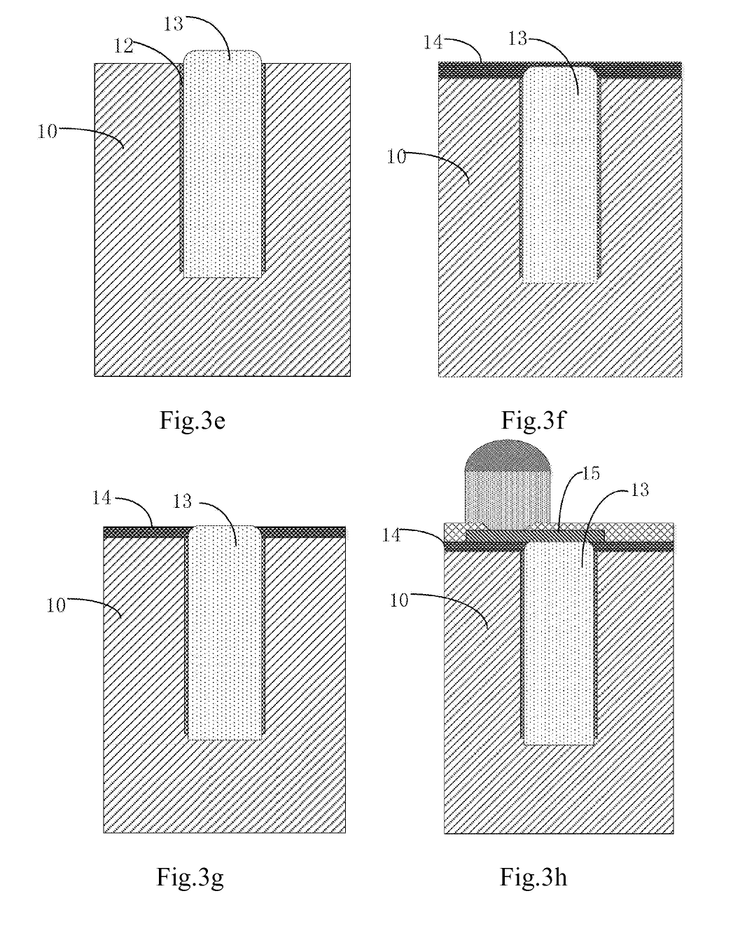

FIG. 3a-3h illustrates the flow diagram of a TSV front-top interconnection process in an embodiment. As shown in FIG. 3, in an embodiment of the present invention, the TSV front-top interconnection process specifically includes following steps:

S1: TSV 11 is etched on the substrate 10, as shown in FIG. 3a.

Firstly, the position of the hole is determined on the substrate 10 surface. The depth of the hole is generally 50˜150 μm, the diameter of the TSV 11 is generally 5˜30 μm. The hole may be made by a semiconductor etching process, or by other feasible ways, such as mechanical drilling, laser drilling, etc.

In an embodiment, TSV is etched by an isotropic dry etching process, as shown in FIG. 3a, and the cross-section of the hole is arc-shaped. The etching process is generally divided into multiple cycles, and in each cycle of the isotropic dry etching process, an arc-shaped structure is produced.

S2: An insulating layer 12 is prepared on the inner wall of the TSV 11 and on the substrate 10 surface, as shown in FIG. 3b.

The insulating layer 12 may be made of oxide, nitride, or other insulating materials. For example, when the substrate is made of silicon, the insulating layer may be made of silicon oxide, silicon nitride, or silicon oxynitride.

The insulating layer 12 may be prepared by oxidizing or nitriding the substrate, or be prepared through a chemical vapor deposition (CVD) process, or a plasma enhanced chemical vapor deposition (PECVD) process, or a low pressure chemical vapor deposition (LP CVD) process, etc.

The insulating layer 12 is mainly used to insulate, to prevent the conductive material of TSV from affecting the carrier variation of the semiconductor.

S3: the TSV and the surface of the insulating layer are electroplated to form a TSV copper pillar. At this situation, due to the TSV etching process, a stress concentration area is generated at the corner of the TSV top, as shown in FIG. 3c.

After the TSV with the insulating layer is prepared, the electroplating process is implemented to form the TSV copper pillar 13 in the TSV 11. The TSV copper pillar 13 is preferably made of metal materials, such as W, Cu, Ag, etc., or other conductive materials, such as doped polycrystalline silicon, or the compounds thereof and so on.

Since the corner of the inner wall of the TSV 11 is arc-shaped, during the preparation of the insulating layer 12 and the TSV copper pillar 13, a stress concentration area 131 with a multilayer structure is generated at the corner of the TSV top.

S4: a CMP process is implemented to remove the substrate with a specific thickness including the TSV copper pillar to further eliminate the stress concentration area at the corner of the TSV top, as shown in FIG. 3d.

In an embodiment, the overburden copper layer, the insulating layer on the substrate 10 surface, part of the substrate and the TSV copper pillar are removed by the CMP process. During the CMP process, the purpose is to completely remove the corner area at the TSV top and further to remove the stress concentration area as much as possible, so it is not necessary to precisely control the thickness of the substrate, or to worry about the insulating layer been worn off.

By reducing or eliminating the stress concentration area of the TSV copper pillar, the possibility of generating delamination or cracks between the insulating layer and substrate due to stress has been reduced.

S5: The TSV copper pillar 13 is annealed to make the TSV copper pillar 13 expose a certain height from the substrate 10 to form a protrusion, as shown in FIG. 3e.

In the prior art, for the TSV with small diameter and high depth-to-width ratio, the TSV copper pillar is much higher than the substrate surface after the annealing process, which should be removed by additional CMP process. However, in the technical scheme of the present invention, the exposing part of the TSV copper pillar (the protrusion) is considered as a part of the interconnect layer, by which a better metal interconnection can be achieved. In this way, the whole technical process is simplified, and the disadvantage is turned into advantage.

S6: A passivation layer 14 is prepared on the surface of the substrate 10 and the TSV copper pillar 13, as shown in FIG. 3f.

Preferably, the passivation layer 14 may be an insulating layer, and its composition may be polymer. It may be prepared by a spin-coating or deposition process, etc.

S7: A certain part of the passivation layer 14 is removed to make the top of the TSV copper pillar 13 expose from the passivation layer, as shown in FIG. 3g.

The certain part of passivation layer may be removed by a plasma etching or a CMP process, as long as the top of the TSV copper pillar is exposed. The exposing TSV copper pillar is considered as a part of the interconnect layer, and used to form the subsequent metal interconnection structure.

S8: A metal interconnection structure of the TSV copper pillar is formed, and the final structure is shown in FIG. 3h.

A redistribution layer (RDL) 15 is prepared above the TSV copper pillar 13 and the passivation layer 14. By using the redistribution layer, bonding pads may be rearranged at any reasonable position on the substrate. Through the RDL technology, the traditional bonding pads in the center of the chip can be re-assigned to the outer substrate (on both sides or either side) and then the substrate may be bonded with an upper substrate through lead wires or metal bumps.

In another embodiment the present invention the TSV front-top interconnection process includes following steps:

S1: a TSV is etched on the substrate.

S2: An insulating layer is prepared on the inner wall of the TSV and the substrate surface.

S3: A seed layer is prepared on the surface of the insulating layer.

S4: the TSV and the surface of the insulating layer are electroplated to form a TSV copper pillar. At this situation, due to the TSV etching process, a stress concentration area is generated at the corner of the TSV top.

S5: a CMP process is implemented to remove the substrate with a specific thickness including the overburden copper of the substrate surface, the seed layer, the insulating layer and certain thickness of the substrate to further eliminate the stress concentration area at the corner of the TSV top.

S6: The TSV copper pillar is annealed to make the TSV copper pillar expose a certain height from the substrate to form a protrusion.

S7: A passivation layer is prepared on the surface of the substrate and the TSV copper pillar.

S8: A certain part of the passivation layer is removed to make the top of the TSV copper pillar (the protrusion) expose from the passivation layer.

S9: A metal interconnection structure of the TSV copper pillar is formed.

In the present embodiment, a seed layer is prepared on the insulating layer, by which the electroplating can be more efficient to form the TSV copper pillar.

In the step S5, The stress concentration area at the top of the TSV copper pillar is also required to be removed by the CMP process, the specific process includes:

The overburden copper layer (including the conductive layer and the seed layer connected with TSV on the surface of the substrate), the seed layer, the insulating layer, a part of the substrate, and a part of the TSV copper pillar in the substrate are removed.

According to the above descriptions, it can be seen that the TSV front-top interconnection process provided in the present invention has following merits:

The stress concentration area of the TSV copper pillar is eliminated, which reduces the possibility of generating delamination or cracks between the insulating layer and the substrate due to stress.

The feature that the TSV copper pillar exposes after the electroplating and annealing process, which was considered as a defect in the prior art, is re-used to implement the interconnection between the TSV copper pillar with the redistribution metal layer;

It is not necessary to precisely control the thickness of the substrate processed by the CMP process, which reduces the difficulty of the CMP process;

The quality and reliability of TSV are improved.

Those skilled in the art can understand that, the present invention should not be limited to the descriptions in the above embodiments; meanwhile, within the spirit and basic features of the present invention, the technical scheme of the present invention can be implemented in other specific forms. Therefore, the embodiments should be considered exemplary and non-restrictive under whichever circumstances. The protection scope of the present invention is restricted by the claims attached rather than the above descriptions. Consequently, all the adjustments in accordance with the principle and the claims are considered within the protection scope of the present invention. Any reference signs in the claims should not be considered as the restriction to the related claims.

Moreover, those skilled in the art can understand that, although this specification is described in the way of embodiments, however, not only one independent technical scheme is included in each embodiment. This way of description is used barely for clarity. For those skilled in the art, this subject matter of the specification should be considered as an entirety. The technical schemes of each embodiment can be properly combined and form as other embodiments that can be understood by those skilled in the art.

1. A TSV front-ends interconnection process, comprising:
etching a TSV on a substrate;
preparing an insulating layer on the inner wall of the TSV and on the substrate surface;
electroplating the TSV and the surface of the insulating layer to form a TSV copper pillar;
implementing a chemical mechanical polishing process to remove a specific thickness of the substrate including the TSV copper pillar;
annealing the TSV copper pillar to make the TSV copper pillar expose a certain height from the substrate;
preparing a passivation layer on the surface of the substrate and the TSV copper pillar;
removing certain part of the passivation layer to make the top of the TSV copper pillar expose from the passivation layer.

2. The process of claim 1, wherein, etching a TSV on a substrate comprises:
etching the TSV on a substrate by an isotropic dry etching process.

3. The process of claim 1, wherein, before electroplating the TSV and the surface of the insulating layer to form a TSV copper pillar, the process further comprises:
preparing a seed layer above the insulating layer.

4. The process of claim 1, wherein, the CMP process comprises:
removing the overburden copper layer on the substrate, the insulating layer, a part of the substrate, and a part of the TSV copper pillar in the substrate to eliminate a stress concentration area.

5. The process of claim 1, wherein, the certain part of the passivation layer is removed by the plasma etching or CMP process.

6. The process of claim 1, further comprising:
preparing a redistribution layer, bonding pads or metal bumps above the TSV copper pillar and the passivation layer.

7. The process of claim 1, wherein, the insulating layer is prepared by oxidizing or nitriding the substrate, through any of a chemical vapor deposition process, a plasma enhanced chemical vapor deposition process, and a low pressure chemical vapor deposition process.

8. The process of claim 1, wherein, the insulating layer is made of oxide, nitride, or other insulating materials.

9. The process of claim 1, wherein, the passivation layer is made of polymer and prepared by a spin-coating or deposition process.

10. The process of claim 1, the TSV copper pillar is made of metal materials.
